(19) United States
(12) Patent Application Publication
(10) Pub. No.: US 2015/0055301 A1
(43) Pub. Date: Feb. 26, 2015

(54) CARD-TYPE ELECTRONIC COMPONENT COOLING STRUCTURE AND ELECTRONIC DEVICE

(71) Applicant: FUJITSU LIMITED, Kawasaki-shi (JP)

(72) Inventors: Tsuyoshi SO, Kawasaki (JP); Hideo Kubo, Kawasaki (JP); Nobumitsu Aoki, Kawasaki (JP); Yoshinori Uzuka, Kawasaki (JP)

(73) Assignee: FUJITSU LIMITED, Kawasaki-shi (JP)

(21) Appl. No.: 14/539,026

(22) Filed: Nov. 12, 2014

Related U.S. Application Data
(63) Continuation of application No. PCT/JP2012/063368, filed on May 24, 2012.

(51) Int. Cl. H05K 7/20

(52) U.S. Cl. CPC H05K 7/20254
USPC 361/701

(57) ABSTRACT

A cooling structure for a card-type electronic component, including: a printed circuit board on which a card-type electronic component is detachably mounted; a thermally-conductive heat transfer member, disposed facing the card-type electronic component; a press contact portion that places the heat transfer member in press contact with the card-type electronic component; and a pair of flow path portions that are disposed at both width direction sides of the card-type electronic component, that form flow paths in which coolant flows, and that support the heat transfer member so as to enable heat exchange between the heat transfer member and the coolant.

### CROSS-REFERENCE TO RELATED APPLICATION

This application is a continuation application of International Application No. PCT/JP2012/063368, filed May 24, 2012, the disclosure of which is incorporated herein by reference in its entirety.

### FIELD

The embodiments discussed herein are related to a cooling structure for a card-type electronic component, and an electronic device.

### BACKGROUND

A known water-cooled cooling device includes a pair of heat transfer plates that make press contact with a memory card, detachably mounted to a printed circuit board, from both sides, and a heat sink integrally provided at upper end portions of the pair of heat transfer plates, that dissipates heat of the memory card to the coolant through the pair of heat transfer plates.

### RELATED PATENT DOCUMENTS

Japanese Laid-open Patent Publication No. 2010-040886

Japanese Laid-open Patent Publication No. 63-299258

Japanese Laid-open Patent Publication No. 2004-079940

In the above cooling device, the heat sink is disposed above the memory card, and the memory card is replaced after removing the heat sink.

### SUMMARY

According to an aspect of the embodiments, a cooling structure for a card-type electronic component includes: a printed circuit board on which a card-type electronic component is detachably mounted; a thermally-conductive heat transfer member, disposed facing the card-type electronic component; a press contact portion that places the heat transfer member in press contact with the card-type electronic component; and a pair of flow path portions that are disposed at both width direction sides of the card-type electronic component, that form flow paths in which coolant flows, and that support the heat transfer member so as to enable heat exchange between the heat transfer member and the coolant.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a perspective view illustrating an electronic device according to a first exemplary embodiment;

FIG. 2 is an exploded perspective view illustrating a printed circuit board applied with a card-type electronic component cooling structure according to the first exemplary embodiment;

FIG. 3 is an exploded perspective view illustrating a heat transfer member, a flow path member, and a press contact restriction member according to the first exemplary embodiment;

FIG. 4 is a perspective view illustrating a printed circuit board applied with a card-type electronic component cooling structure according to the first exemplary embodiment;

FIG. 5 is a cross-section illustrating the printed circuit board illustrated in FIG. 4, taken along the width direction of a memory card;

FIG. 6 is an overall perspective view illustrating the heat transfer member illustrated in FIG. 3;

FIG. 7 is a cross-section taken along line 7-7 in FIG. 5, illustrating the heat transfer members in a separated state from the memory chips;

FIG. 8 is a cross-section taken along line 7-7 in FIG. 5, illustrating the heat transfer members in a press contact state with the memory chips;

FIG. 9 is a cross-section corresponding to FIG. 7, illustrating a modified example of the first exemplary embodiment;

FIG. 10 is a cross-section corresponding to FIG. 7, illustrating a printed circuit board applied with a card-type electronic component cooling structure of a second exemplary embodiment;

FIG. 11 is a cross-section corresponding to FIG. 8, illustrating a printed circuit board applied with a card-type electronic component cooling structure of the second exemplary embodiment;

FIG. 12 is a cross-section corresponding to FIG. 7, illustrating a printed circuit board applied with a card-type electronic component cooling structure of a third exemplary embodiment;

FIG. 13 is a cross-section corresponding to FIG. 8, illustrating a printed circuit board applied with a card-type electronic component cooling structure of the third exemplary embodiment;

FIG. 14 is a cross-section corresponding to FIG. 7, illustrating a printed circuit board applied with a card-type electronic component cooling structure of a fourth exemplary embodiment;

FIG. 15 is a cross-section corresponding to FIG. 8, illustrating a printed circuit board applied with a card-type electronic component cooling structure of the fourth exemplary embodiment;

FIG. 16 is a cross-section corresponding to FIG. 7, illustrating a modified example of the first exemplary embodiment; and

FIG. 17 is a face-on view illustrating a modified example of a heat transfer member of the first exemplary embodiment.

### DESCRIPTION OF EMBODIMENTS

Explanation follows regarding exemplary embodiments of a cooling structure of a card-type electronic component, and regarding an electronic device, with reference to the drawings. Note that in each of the drawings the arrow H indicates the height direction (up-down direction) of the electronic device as appropriate. The arrow W indicates the width direction of the electronic device. The arrow D indicates the depth direction of the electronic device.

First, explanation is given regarding a first exemplary embodiment.

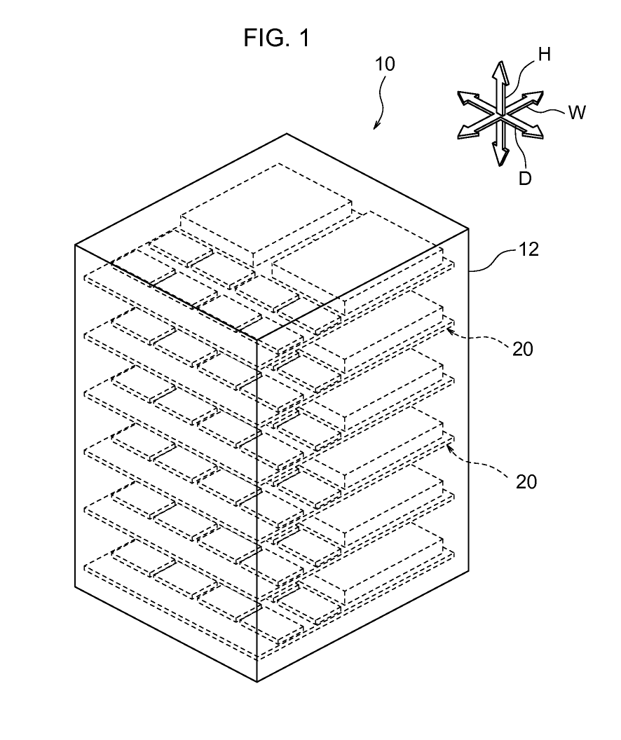

As illustrated in FIG. 1, an electronic device 10 includes a casing 12. The casing 12 houses plural printed circuit boards 20 to which the card-type electronic component cooling structure 70 (referred to below simply as the “cooling structure”) according to the first exemplary embodiment is applied. The printed circuit boards 20 are configured with their plate thickness direction along the height direction of the casing 12 (arrow H direction), and are disposed at intervals in the plate thickness direction.

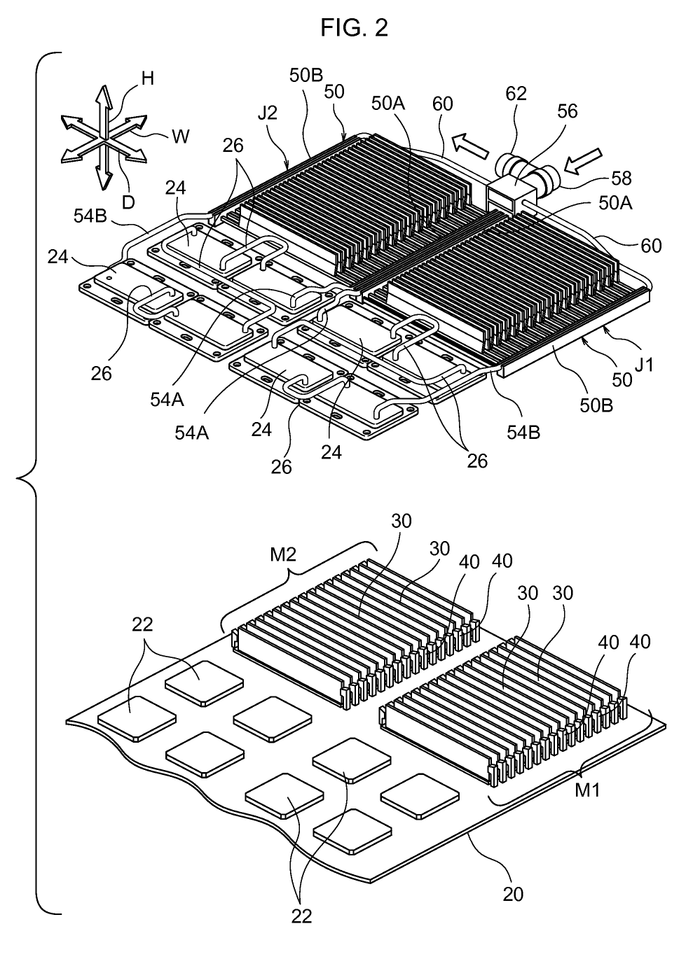

As illustrated in FIG. 2, the printed circuit boards 20 are configured by, for example, a main board (motherboard) on which are mounted plural (8 in the present exemplary embodiment) Central Processing Units (CPU) 22. The CPUs 22 are provided on the front face of the printed circuit board 20 at one width direction (arrow W direction) end side of the casing 12. The plural CPUs 22 are arrayed at intervals in the width direction and depth direction of the casing 12.

A heat sink 24, serving as an example of a cooling heat exchanger that cools the CPUs 22, is disposed over each of the CPUs 22. Each heat sink 24 is formed with an internal flow path within which coolant flows, and is, for example, fixed to the printed circuit board 20 by screws, not illustrated in the drawings. The heat sinks 24 are split into two sets, corresponding to the number of coolant circulation paths J1, J2, described later. In each of the sets, plural (4 in the present exemplary embodiment) of the heat sinks 24 are connected in series via tubes 26, such that coolant flows through the internal flow paths. The coolant that flows in the internal flow paths of each of the heat sinks 24 undergoes heat exchange with the CPUs 22 (see FIG. 2), thereby cooling the CPUs 22 by removing heat from the CPUs 22.

Plural memory cards 30 are disposed at the casing 12 width direction other end side of the front faces of the printed circuit boards 20. The memory cards 30 are arrayed in two rows in the depth direction of the casing 12, with an interval therebetween. The plural memory cards 30 configuring each row are respectively referred to as memory card groups M1, M2. The plural memory cards 30 configuring each of the memory card groups M1, M2 are configured with their plate thickness direction along the casing 12 width direction, and are arrayed at intervals in the plate thickness direction. The memory cards 30 are disposed with their width direction (length direction) along the casing 12 depth direction, and are detachably mounted to the printed circuit board 20 through memory sockets 40 mounted to the front face of the printed circuit board 20. Note that the front face of each of the printed circuit boards 20 is formed with electrical circuits, not illustrated in the drawings, electrically connecting the plural CPUs 22 and memory sockets 40.

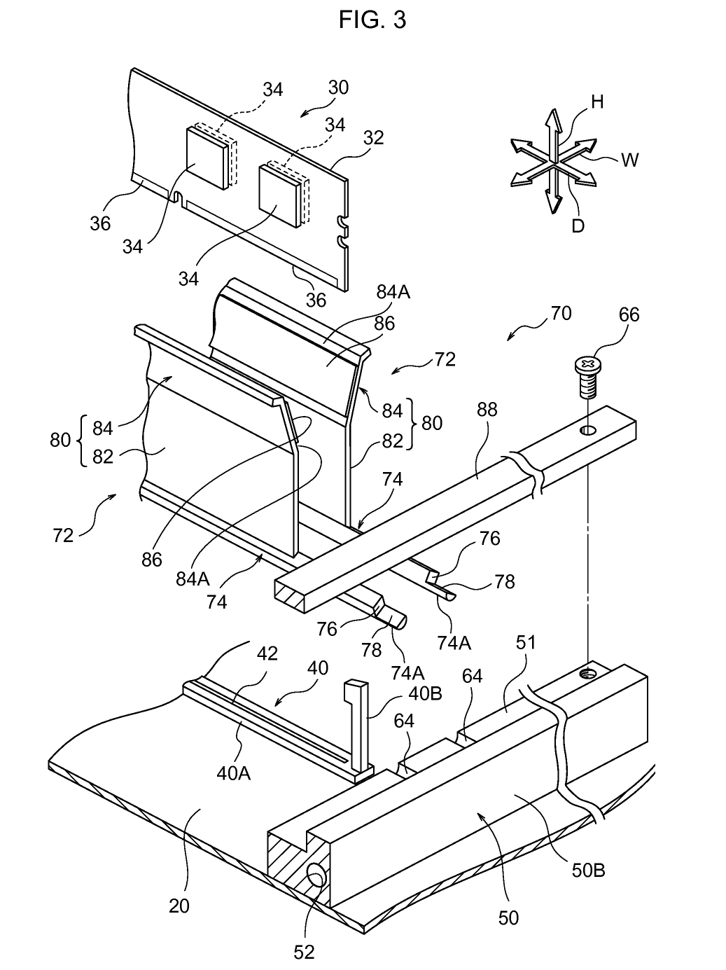

As illustrated in FIG. 3, each of the memory cards 30, serving as an example of a card-type electronic component, includes a memory board 32 and plural memory chips (memory ICs) 34 respectively mounted on both faces of the memory board 32. The plural memory chips 34 are arrayed facing each other across the memory board 32, at intervals in the memory card 30 width direction (arrow D direction). An end portion on the printed circuit board 20 side (lower end portion) of the memory board 32 is provided with a connection portion 36 that electrically connects to the memory socket 40 mounted on the printed circuit board 20.

The memory sockets 40 are disposed with their length direction along the depth direction of the casing 12. The memory sockets 40 each include a socket main body portion 40A, and a pair of board guide portions 40B that guide the memory board 32 to the socket main body portion 40A. The socket main body portion 40A is formed with a connection opening 42, into which the connection portion 36 of the memory board 32 is removably inserted. The connection portion 36 of the memory board 32 is inserted into the connection opening 42 to electrically connect the respective memory chips 34 mounted on the memory board 32 to the CPUs 22 (see FIG. 2) mounted to the printed circuit boards 20.

The pair of board guide portions 40B are provided at both length direction end portions of the socket main body portion 40A. Note that only one of the board guide portions 40B out of the pair of board guide portions 40B is illustrated in FIG. 3. The memory board 32 is capable of insertion between the pair of board guide portions 40B. Both width direction end portions of the memory board 32 are slidably supported by the board guide portions 40B, thereby guiding the connection portion 36 of the memory board 32 to the connection opening 42 of the socket main body portion 40A.

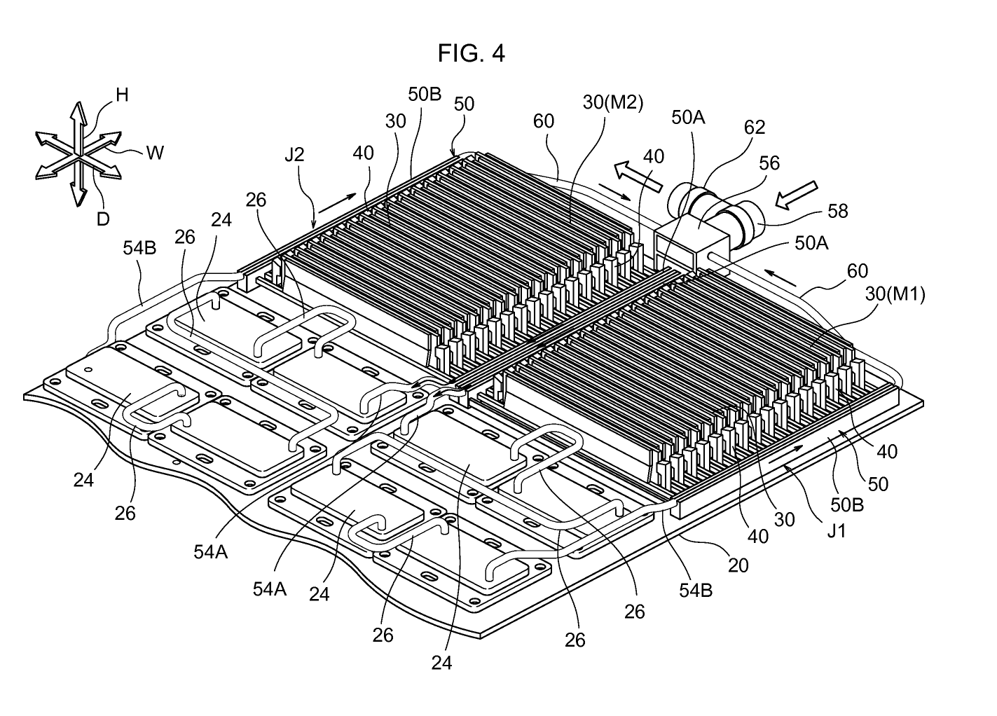

As illustrated in FIG. 4, the coolant circulation paths J1, J2, inside which circulate a coolant such as cooling water, are respectively provided at the peripheries of the respective memory card groups M1, M2. The circulation direction of the coolant circulating in the coolant circulation paths J1, J2 is indicated by arrows in FIG. 4. The coolant circulation paths J1, J2 are connected through a multi-connector 56, described later, to a tank, not illustrated in the drawings, provided to the casing 12 (see FIG. 1). Coolant is stored in the tank. The casing 12 is also provided with a pump, not illustrated in the drawings, that is driven to circulate the coolant between the coolant circulation paths J1, J2 and the tank. The coolant circulation paths J1, J2 are connected to the tank through a cooler (heat exchanger), not illustrated in the drawings, that dissipates heat in the coolant to the atmosphere. Coolant that has cooled in the cooler is supplied to the coolant circulation paths J1, J2 from the tank.

Detailed explanation follows regarding configuration of the coolant circulation paths J1, J2. Since the coolant circulation path J2 is of similar configuration to the coolant circulation path J1, the configuration of the coolant circulation path J1 provided at the periphery of the memory card group M1 is explained in detail, and explanation regarding the configuration of the coolant circulation path J2 provided at the periphery of the memory card group M2 is omitted where appropriate.

The coolant circulation path J1 includes a pair of flow path members 50A, 50B, serving as an example of a pair of flow path portions. The pair of flow path members 50A, 50B are respectively disposed at both width direction sides of the plural memory cards 30 configuring the memory card group M1. Namely, the pair of flow path members 50A, 50B are disposed at positions away from a mounting path of the memory cards 30 to the printed circuit board 20. Note that the width direction of the memory cards 30 referred to here is a direction orthogonal to the mounting direction of the memory cards 30 to the printed circuit board 20, and also orthogonal to the plate thickness direction of the memory cards 30.

The pair of flow path members 50A, 50B are connected to the plural heat sinks 24 through connection tubes 54A, 54B, described later, to give a configuration in which the coolant flows in sequence through the flow path member 50A, the plural heat sinks 24, and the flow path member 50B. In other words, in the present exemplary embodiment the pair of flow path members 50A, 50B are provided on a circulation path through which the coolant circulates to the plural heat sinks 24.

The pair of flow path members 50A, 50B are formed from a thermally-conductive metal (such as copper), are disposed with their length direction along the array direction of the memory cards 30 (the arrow W direction), and are fixed to the front face of the printed circuit boards 20, for example, by screws, not illustrated in the drawings. Coolant flow paths 52 (see FIG. 3), serving as an example of flow paths, are respectively formed extending along the length direction inside the respective flow path members 50A, 50B.

Out of the pair of flow path members 50A, 50B, one length direction end portion of one (the memory card group M2 side) flow path member 50A is connected to the multi-connector 56. The multi-connector 56 is provided with a supply connector 58 connected to the tank, not illustrated in the drawings, mentioned above. The coolant stored in the tank is supplied from the supply connector 58 and through the multi-connector 56 to the coolant flow path 52 of the flow path member 50A.

A length direction other end portion of the one flow path member 50A is connected through the connection tube 54A to the heat sink 24 positioned furthest upstream out of the plural serially connected heat sinks 24. The length direction other end portion of the other flow path member 50B is connected through the connection tube 54B to the heat sink 24 positioned furthest downstream out of the plural serially connected heat sinks 24. The coolant supplied through the multi-connector 56 accordingly flows in sequence through the coolant flow path 52 of the one flow path member 50A (see FIG. 3), the plural heat sinks 24, and the coolant flow path 52 of the other flow path member 50B.

The one length direction end portion of the other flow path member 50B is connected to the multi-connector 56 through a discharge tube 60. A discharge connector 62 connected to the tank, not illustrated in the drawings, is provided to the multi-connector 56. Coolant that has flowed through the coolant flow path 52 of the flow path member 50B is returned to the tank through the discharge connector 62.

Explanation follows regarding a cooling structure 70 that cools the memory cards 30.

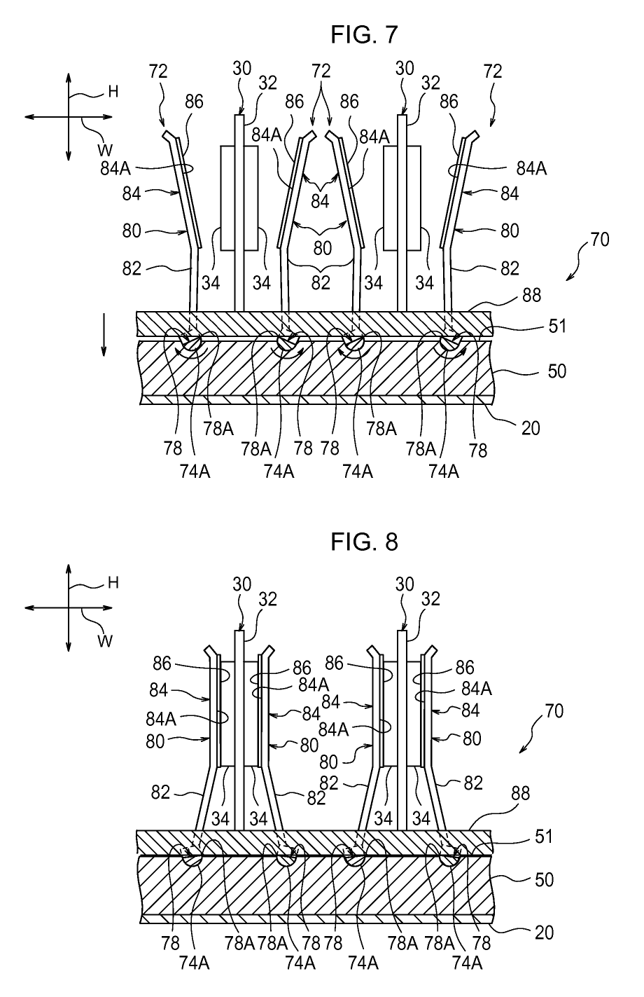

As illustrated in FIG. 3, the cooling structure 70 includes the pair of flow path members 50 described above, heat transfer members 72, and a pair of press contact restriction members 88 serving as an example of a press contact portion. In the present exemplary embodiment, pairs of the heat transfer members 72 are disposed facing in opposite directions to each other on both plate thickness direction sides of the memory cards 30. Viewed another way, in the present exemplary embodiment pairs of the heat transfer members 72 are disposed facing in opposite directions to each other between pairs of plate thickness direction adjacent memory cards 30, as illustrated in FIG. 7.

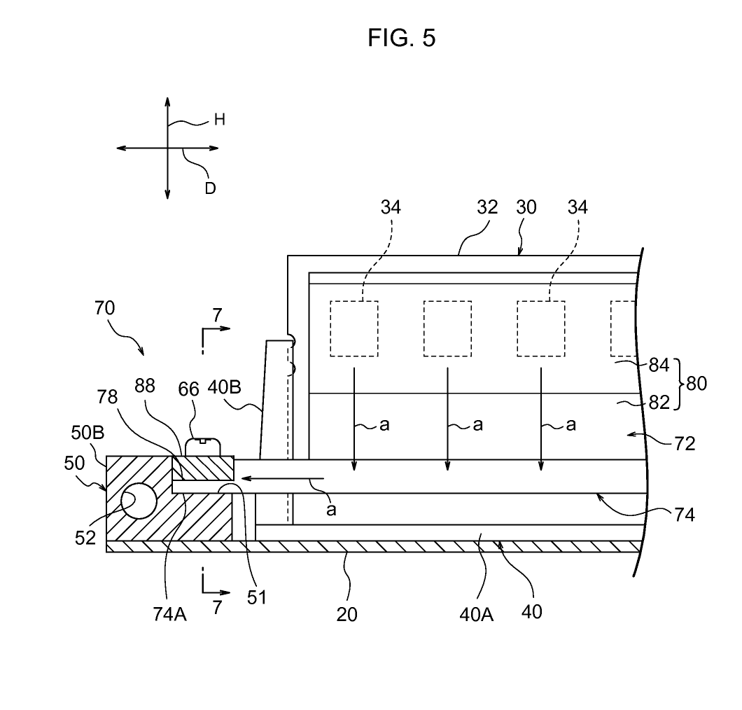

As illustrated in FIG. 3 and FIG. 5, the pairs of heat transfer members 72 are formed from a thermally-conductive metal (such as copper). Each the heat transfer members 72 includes a shaft portion 74 rotatably supported on the pair of flow path members 50, and a plate-shaped portion 80 that faces the memory card 30. Each of the heat transfer members 72 spans between the pair of flow path members 50, with both axial direction end portions 74A of the respective heat transfer members 72 inserted into recess portions 64 formed to fixing faces 51 of the pair of flow path members 50, so as to be capable of heat exchange therewith. Note that FIG. 3 and FIG. 5 only illustrate one axial direction end portion 74A of the shaft portions 74.

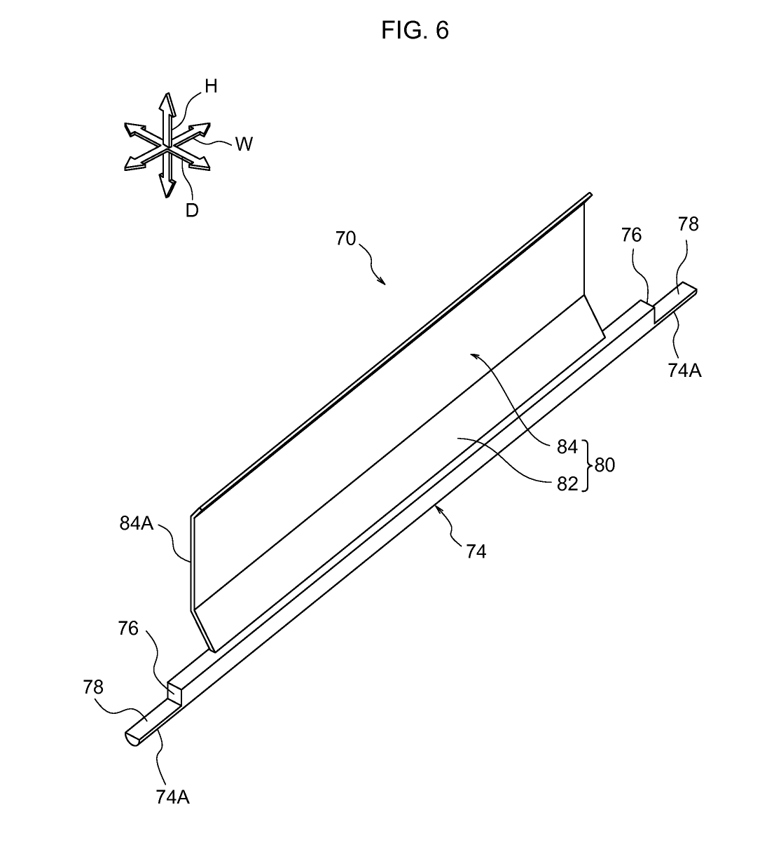

As illustrated in FIG. 6, notch portions 76 are respectively formed at both end portions 74A of the shaft portion 74 of the heat transfer member 72, such that both end portions 74A have a semicircular cross-section profile. Both end portions 74A of the shaft portion 74 are formed with a flat plane shaped engagement face 78, serving as an example of an engagement portion. The engagement faces 78 respectively engage with the pair of press contact restriction members 88, described later.

As illustrated in FIG. 3 and FIG. 5, the plate-shaped portion 80 is provided at an axial direction intermediate portion of the shaft portion 74. The plate-shaped portion 80 is formed in a plate shape, and extends out from the axial direction intermediate portion of the shaft portion 74 to face the memory card 30. The plate-shaped portion 80 includes a base portion 82, configuring the shaft portion 74 side, and a facing portion 84 that configures an extension direction leading end side of the plate-shaped portion 80 and faces the plural memory chips 34 mounted on the memory card 30.

As illustrated in FIG. 7 and FIG. 8, the facing portions 84 of the heat transfer members 72 contact the plural memory chips 34 mounted on both sides of the memory cards 30 accompanying rotation of the shaft portions 74, so as to be capable performing heat exchange with the memory chips 34. Heat in the respective memory chips 34 is thereby transmitted through the heat transfer members 72 to the coolant flowing in the coolant flow paths 52 of the pair of flow path members 50. Namely, the heat of the respective memory chips 34 is discharged into the coolant flowing in the coolant flow paths 52 of the pair of flow path members 50. The respective memory chips 34 are thus cooled. Note that the memory sockets 40 are omitted from illustration in FIG. 7 and FIG. 8.

The facing portion 84 of the heat transfer member 72 is inclined to the opposite side to the memory card 30 with respect to the base portion 82, thereby facilitating face-to-face contact with the plural memory chips 34. Moreover, a heat transfer sheet 86, that has both thermally-conductive and elastic properties, is applied to a contact face 84A of the facing portion 84, contacting the memory chips 34. The facing portion 84 contacts the plural memory chips 34 with the heat transfer sheet 86 interposed therebetween.

The pair of press contact restriction members 88 fix the heat transfer members 72 to the pair of flow path members 50, and are respectively disposed running along the fixing faces 51 of the pair of flow path members 50. The respective press contact restriction members 88 are placed on the fixing faces 51 of the flow path members 50 from above the engagement faces 78 formed to both end portions 74A of the shaft portions 74 of the heat transfer members 72. Both length direction end portions of the respective press contact restriction members 88 are fixed to the fixing faces 51 of the flow path members 50 by screws 66 (see FIG. 3), serving as an example of fixing members. The end portions 74A of the shaft portions 74 are thereby prevented from coming out of the recess portions 64 formed to the fixing faces 51. Moreover, the press contact restriction members 88 engage with the engagement faces 78 formed to the end portions 74A of the shaft portions 74, thereby restricting rotation of the shaft portions 74 with respect to the pair of flow path members 50 in a state in which the facing portions 84 of the heat transfer members 72 is in press contact with the plural memory chips 34.

Explanation follows regarding an installation and removal method (replacement method) of the memory cards 30 in the first exemplary embodiment, together with explanation regarding operation of the first exemplary embodiment.

As described above, the memory cards 30 are mounted to the printed circuit boards 20 through the memory sockets 40. In this state, as illustrated in FIG. 7, a pair of the heat transfer members 72 facing in opposite directions to each other are disposed on both sides of each memory card 30, with both end portions 74A of the shaft portions 74 of the respective heat transfer members 72 respectively inserted into the recess portions 64 formed to the fixing faces 51 of the pair of flow path members 50. The facing portions 84 of the pair of heat transfer members 72 respectively face the plural memory chips 34 mounted on both sides of the memory card 30.

Next, the pair of press contact restriction members 88 are respectively placed over the fixing faces 51 of the pair of flow path members 50. When this is performed, the pair of press contact restriction members 88 respectively contact edge portions 78A of the engagement faces 78 formed to both end portions 74A of the shaft portions 74 of the heat transfer members 72. In this state, the pair of press contact restriction members 88 are respectively fixed to the fixing faces 51 of the pair of flow path members 50 by the screws 66 (see FIG. 3). When this is performed, as the screws 66 are tightened onto the flow path members 50, the pair of press contact restriction members 88 press the edge portions 78A of the engagement faces 78 toward the printed circuit board 20 side, thereby rotating the pair of heat transfer members 72 in mutually approaching directions about their respective shaft portions 74. As illustrated in FIG. 8, the facing portions 84 of the pair of heat transfer members 72 accordingly make press contact with the plural memory chips 34 mounted on both sides of the memory card 30, with the heat transfer sheets 86 interposed therebetween.

When the facing portions 84 of the heat transfer members 72 make press contact with the plural memory chips 34, the pair of press contact restriction members 88 respectively engage with the engagement faces 78 formed to both end portions 74A of the shaft portions 74. Rotation of the shaft portions 74 is thereby restricted, retaining the facing portions 84 of the heat transfer members 72 in a press contact state with the plural memory chips 34.

As illustrated by the arrows a in FIG. 5, heat of the respective memory chips 34 is transmitted through the heat transfer member 72 to the coolant inside the coolant flow paths 52 of the pair of flow path members 50 due to the press contact between the facing portion 84 of the heat transfer member 72 and the plural memory chips 34, with the heat transfer sheet 86 interposed therebetween. Namely, heat exchange occurs between the plural memory chips 34 and the coolant flowing in the coolant flow paths 52 through the heat transfer member 72 and the pair of flow path members 50. As a result, the heat of the plural memory chips 34 is discharged into the coolant flowing in the coolant flow paths 52, thus cooling the respective memory chips 34.

When replacing the memory cards 30, the screws 66 that fix the pair of press contact restriction members 88 to the pair of flow path members 50 are loosened, releasing the engagement between the respective press contact restriction members 88 and the engagement faces 78 formed to both end portions 74A of the shaft portions 74. The shaft portions 74 therefore become rotatable with respect to the pair of flow path members 50. The pair of heat transfer members 72 are then rotated about their shaft portions 74 in directions heading apart from each other, thereby separating the respective facing portions 84 of the heat transfer members 72 from the plural memory chips 34 mounted on both sides of the memory card 30. The memory cards 30 are replaced in this state.

Then, in a similar process to that described above, the screws 66 that fix the pair of press contact restriction members 88 to the pair of flow path members 50 are tightened, and the facing portions 84 of the pair of heat transfer members 72 make press contact with the plural memory chips 34 mounted on both sides of the replacement memory card 30. The respective memory chips 34 accordingly undergo heat exchange with the coolant flowing in the coolant flow path 52 through the heat transfer members 72 and the pair of flow path members 50, thus cooling the memory chips 34.

In the present exemplary embodiment, the memory cards 30 can accordingly be replaced without removing the pair of flow path members 50 from the printed circuit board 20, due to disposing the pair of flow path members 50 at both width direction sides of the memory card 30. There is therefore no need to reconnect the pair of flow path members 50 to the heat sinks 24, thus reducing the effort demanded by an installation and removal operation (replacement operation) of the memory cards 30.

Tightening the screws 66 that fix the pair of press contact restriction members 88 to the fixing faces 51 of the pair of flow path members 50 enables the respective facing portions 84 of the pairs of heat transfer members 72 to be placed in press contact with the plural memory chips 34 mounted on both sides of the memory cards 30. The effort demanded by an installation and removal operation of the memory cards 30 is accordingly reduced in comparison to cases in which the facing portions 84 of the pairs of heat transfer members 72 are individually placed in press contact with the plural memory chips 34 mounted on both sides of the memory cards 30.

Moreover, in the present exemplary embodiment, the facing portions 84 of the pair of heat transfer members 72 make press contact with a single memory card 30 from both plate thickness direction sides. Deformation (flexing) of the memory card 30 is accordingly suppressed in comparison to cases in which the facing portion 84 of the heat transfer member 72 makes press contact with a single memory card 30 from one plate thickness direction side only. Damage to the memory card 30 is accordingly suppressed.

Moreover, loosening the screws 66 that fix the pair of press contact restriction members 88 to the fixing faces 51 of the pair of flow path members 50 enables the respective facing portions 84 of the pair of heat transfer members 72 to be moved away from the plural memory chips 34 mounted on both sides of the memory card 30. The pair of heat transfer members 72 are thereby suppressed from impinging on the memory card 30 during replacement of the memory card 30. Damage to the memory card 30 is accordingly further suppressed.

Moreover, in the present exemplary embodiment, the facing portion 84 of the heat transfer member 72 makes press contact with the plural memory chips 34 mounted on the memory card 30, with the heat transfer sheet 86 interposed therebetween. The heat transfer sheet 86 absorbs thickness variation and the like between the plural memory chips 34, improving heat transmission efficiency between the plural memory chips 34 and the facing portion 84. The cooling efficiency of the plural memory chips 34 is accordingly improved.

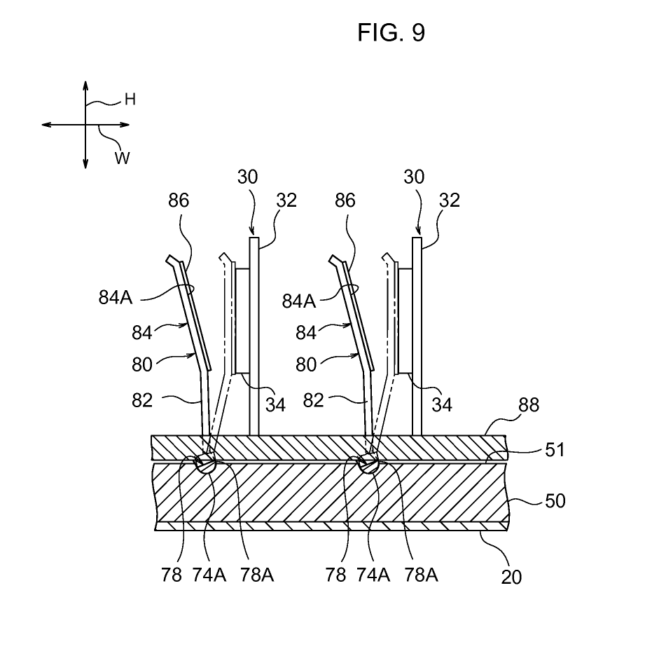

In the present exemplary embodiment, explanation has been given regarding an example in which plural memory chips 34 are mounted on both faces of the memory board 32 of the memory card 30. However, as illustrated in FIG. 9, plural memory chips 34 may be mounted on one face of the memory board 32 only. In such cases, it is sufficient to dispose a single heat transfer member 72 between a pair of plate thickness direction adjacent memory cards 30.

In the present exemplary embodiment, the engagement faces 78 are respectively formed to both end portions 74A of the shaft portion 74 of the heat transfer member 72, however it is sufficient to form the engagement face 78 to at least one out of both end portions 74A of the shaft portion 74.

Explanation follows regarding a second exemplary embodiment. Note that configuration similar to the first exemplary embodiment is allocated the same reference numerals, and explanation is omitted where appropriate.

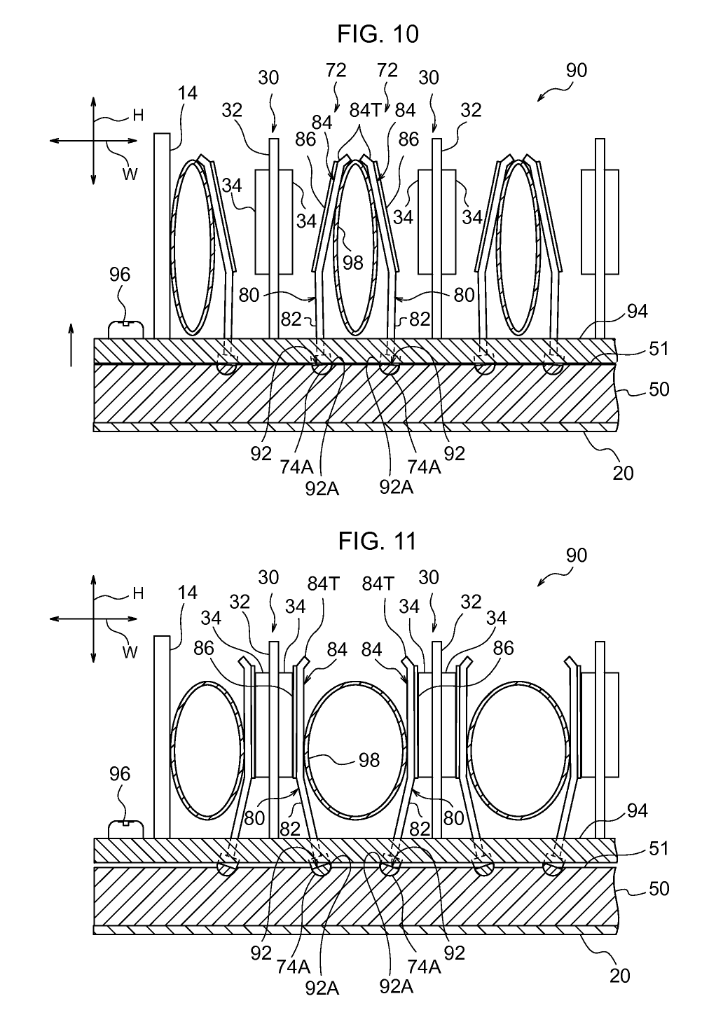

As illustrated in FIG. 10 and FIG. 11, in a cooling structure 90 according to the second exemplary embodiment, pairs of heat transfer members 72 are disposed between memory cards 30 adjacent in the plate thickness direction so as to face in opposite directions to each other. One of each pair of heat transfer members 72 faces one of the pair of adjacent memory cards 30, and the other of the pair of heat transfer members 72 faces the other of the pair of adjacent memory cards 30. Flat plane shaped engagement faces 92, serving as an example of engagement portions, are respectively formed at both end portions 74A of the shaft portions 74 of the pairs of heat transfer members 72. The engagement faces 92 respectively engage with a pair of separation restriction members 94. Note that FIG. 10 and FIG. 11 only illustrate one separation restriction member 94 out of the pair of separation restriction members 94.

The pair of separation restriction members 94 fix the heat transfer members 72 to the pair of flow path members 50, and are respectively disposed running along the fixing faces 51 of the flow path members 50. The respective separation restriction members 94 are placed on the fixing faces 51 from above the engagement faces 92 formed at both end portions 74A of the shaft portions 74 of the heat transfer members 72. Both length direction end portions of the separation restriction members 94 are fixed to the respective fixing faces 51 of the flow path members 50 by screws 96, serving as an example of fixing members. The end portions 74A of the shaft portions 74 are thus suppressed from coming out of the recess portions 64 formed to the fixing faces 51. The separation restriction members 94 respectively engage with the engagement faces 92 formed at both end portions 74A of the shaft portions 74, restricting rotation of the shaft portions 74 with respect to the pair of flow path members 50 in a state in which the facing portions 84 of the heat transfer members 72 are separated from the memory chips 34.

Compression resilient bodies 98, serving as an example of press contact portions, are disposed between the plate-shaped portions 80 of each pair of heat transfer members 72. The compression resilient body 98 is formed from a tube shaped plate spring, and is disposed in a compressed state between the plate-shaped portions 80 of the pair of heat transfer members 72. The compression resilient body 98 biases the plate-shaped portions 80 of the pair of heat transfer members 72 in directions heading apart from each other. Namely, the compression resilient body 98 respectively biases each of the plate-shaped portions 80 of the pair of heat transfer members 72 toward the opposing memory card 30. Note that the compression resilient body 98 on the left end in FIG. 10 and FIG. 11 is disposed between a restriction wall portion 14 attached to the printed circuit board 20 and the heat transfer member 72.

In the facing portions 84 of the pair of heat transfer members 72, free end portions (upper end portions) on the opposite side to the flow path members 50 are provided with stopper portions 84T that respectively project out toward the side of their counterpart. The stopper portions 84T hook over the compression resilient body 98, suppressing the compression resilient body 98 from coming out (springing out) from between the pair of heat transfer members 72.

Next, explanation follows regarding an installation and removal method (replacement method) of the memory cards 30 in the second exemplary embodiment, together with explanation regarding operation of the second exemplary embodiment.

As illustrated in FIG. 10, when mounting the memory cards 30 to the printed circuit board 20, the pair of separation restriction members 94 are respectively placed on the fixing faces 51 of the pair of flow path members 50. When this is performed, the pair of press contact restriction members 94 respectively contact edge portions 92A of the engagement faces 92 formed at both end portions 74A of the shaft portions 74 of the heat transfer members 72. In this state, the screws 96 that fix the pair of separation restriction members 94 to the pair of flow path members 50 are tightened, rotating the pairs of heat transfer members 72 in directions approaching each other, and the pair of separation restriction members 94 engage with the respective engagement faces 92 of the pairs of heat transfer members 72. Rotation of the shaft portions 74 with respect to the pair of flow path members 50 is accordingly restricted in a state in which the facing portions 84 of the heat transfer members 72 are separated from the memory chips 34 of the memory cards 30. Moreover, rotating the pair of heat transfer members 72 in directions approaching each other compresses the compression resilient body 98 between the plate-shaped portions 80 of the pair of heat transfer members 72. The memory cards 30 are mounted to the printed circuit board 20 through the memory sockets 40 (see FIG. 3) in this state.

Next, the screws 96 fixing the pair of separation restriction members 94 to the pair of flow path members 50 are loosened, releasing the engagement between the pair of separation restriction members 94 and the engagement faces 92 of the pairs of heat transfer members 72. Rotation of the shaft portions 74 of the pair of heat transfer members 72 with respect to the pair of flow path members 50 is accordingly enabled. As a result, the pairs of heat transfer members 72 respectively rotate in directions heading apart from each other under the biasing force of the compression resilient bodies 98, and the facing portions 84 of the respective heat transfer members 72 make press contact with the memory chips 34 of the memory cards 30, with the heat transfer sheets 86 interposed therebetween. Heat of the memory chips 34 is accordingly transmitted to the pair of flow path members 50 through the heat transfer members 72, thereby cooling the memory chips 34.

During replacement of the memory card 30, the screws 66 that fix the pair of separation restriction members 94 to the pair of flow path members 50 are tightened as described above, and the pair of separation restriction members 94 respectively engage with the engagement faces 92 of the pairs of heat transfer members 72. Rotation of the shaft portions 74 with respect to the pair of flow path members 50 is accordingly restricted in a state in which the facing portions 84 of the pairs of heat transfer members 72 are separated from the memory chips 34. The memory cards 30 are replaced in this state.

In the present exemplary embodiment, loosening the screws 96 that fix the pair of separation restriction members 94 to the pair of fixing faces 51 of the flow path members 50 enables the respective facing portions 84 of the pairs of heat transfer members 72 to be placed in press contact with the memory chips 34 of the memory cards 30. The effort demanded by an installation and removal operation of the memory card 30 is accordingly reduced in comparison to cases in which the facing portions 84 of the pairs of heat transfer members 72 are individually placed in press contact with the memory chips 34 of the pairs of adjacent memory cards 30.

Tightening the screws 96 that fix the pair of separation restriction members 94 to the fixing faces 51 of the pair of flow path members 50 enables the respective facing portions 84 of the pairs of heat transfer members 72 to be moved away from the memory chips 34 of the opposing memory cards 30. The pair of heat transfer members 72 are thereby suppressed from impinging on the memory card 30 during replacement of the memory card 30. Damage to the memory card 30 is accordingly further suppressed.

The biasing force of the compression resilient bodies 98 places the facing portions 84 of the heat transfer members 72 in press contact with the memory chips 34 of the memory cards 30, thereby improving close contact properties between the facing portions 84 and the memory chips 34. The cooling efficiency of the memory chips 34 is accordingly improved.

Note that in the present exemplary embodiment, the engagement faces 92 are respectively formed at both end portions 74A of the shaft portion 74 of the heat transfer member 72, however it is sufficient to form the engagement face 92 to at least one out of both end portions 74A of the shaft portion 74.

Next, explanation follows regarding a third exemplary embodiment. Note that configuration similar to the first and second exemplary embodiments is allocated the same reference numerals, and explanation is omitted where appropriate.

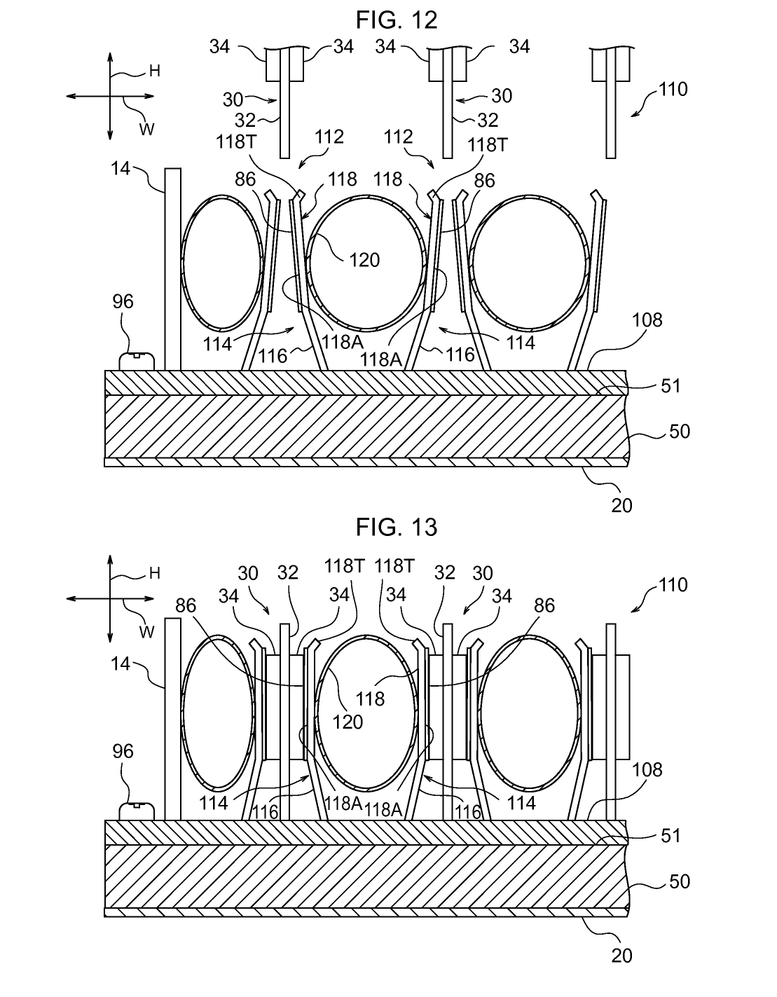

As illustrated in FIG. 12 and FIG. 13, in a cooling structure 110 according to the third exemplary embodiment, pairs of heat transfer members 112 are disposed facing in opposite directions to each other between pairs of plate thickness direction adjacent memory cards 30. One of each pair of heat transfer members 112 is disposed facing one of the pair of adjacent memory cards 30, and the other of the pair of heat transfer members 112 is disposed facing the other of the pair of adjacent memory cards 30. The respective heat transfer members 112 are thermally-conductive, and are formed from, for example, resilient plate springs that are capable of moving toward and away from the opposing memory cards 30.

Each pair of the heat transfer members 112 includes a plate-shaped portion 114 that is formed in a plate shape and extends out from a pair of support members 108, described later, to face the memory card 30. The plate-shaped portion 114 includes a base portion 116 that is joined to the support member 108, for example by welding, and a facing portion 118 that configures an extension direction leading end side of the plate-shaped portion 114, and faces the plural memory chips 34 mounted on one side of the memory card 30. The facing portion 118 contacts the plural memory chips 34 accompanying resilient deformation of the plate-shaped portion 114, so as to be capable of heat exchange therewith. The facing portion 118 is inclined toward the opposite side to the memory card 30 with respect to the base portion 116, thereby facilitating face-to-face contact with the plural memory chips 34. Moreover, a heat transfer sheet 86 is applied to a contact face 118A of the facing portion 118, contacting the memory chips 34. Stopper portions 118T are respectively provided to free end portions (upper end portions) of each of the facing portions 118.

A compression resilient body 120, serving as an example of a press contact portion, is disposed between each pair of heat transfer members 112. The compression resilient body 120 is formed from a tube shaped plate spring, and is disposed with length direction along the width direction of the memory card 30. The compression resilient body 120 is disposed in a compressed state between the plate-shaped portions 114 of the pair of heat transfer members 112. The compression resilient body 120 biases the plate-shaped portions 114 of the pair of heat transfer members 112 in directions heading apart from each other. Namely, the compression resilient body 120 biases each of the pair of heat transfer members 112 toward the opposing memory card 30.

Note that the compression resilient body 120 on the left end in FIG. 12 and FIG. 13 is disposed between a restriction wall portion 14 attached to the printed circuit board 20 and the heat transfer member 112.

The pair of support members 108 are formed from a thermally-conductive metal (such as copper). The respective support members 108 are disposed running along the fixing faces 51 of the flow path members 50 so as to be capable of heat exchange with the flow path members 50. Both length direction end portions of the support members 108 are fixed to the fixing faces 51 of the flow path members 50 by screws 96, serving as an example of fixing members.

Next, explanation follows regarding an installation and removal method (replacement method) of the memory cards 30 in the third exemplary embodiment, together with explanation regarding operation of the third exemplary embodiment.

As illustrated in FIG. 12, the memory cards 30 are mounted to the printed circuit board 20 in the following manner. Namely, the memory cards 30 are inserted in-between the adjacent heat transfer members 112 where the compression resilient bodies 120 are not disposed, and the memory cards 30 are mounted to the printed circuit board 20 through the memory sockets 40 (see FIG. 3). Accordingly, as illustrated in FIG. 13, the facing portions 118 of each of the heat transfer members 112 respectively make press contact with the memory chips 34 of the memory card 30 due to the compression resilient bodies 120 disposed between the pairs of heat transfer members 112. As a result, heat of the memory chips 34 is transmitted to the pair of flow path members 50 through the heat transfer members 112 and the support members 108, thereby cooling the memory chips 34.

The memory cards 30 are replaced by pulling the memory cards 30 out from between the adjacent heat transfer members 112.

The plural heat transfer members 112 can accordingly be disposed on the printed circuit board 20 by attaching the pair of support members 108, to which the plural heat transfer members 112 are joined, to the fixing faces 51 of the pair of flow path members 50. The effort demanded by an installation and removal operation of the plural heat transfer members 112 to the printed circuit board 20 is accordingly reduced.

Explanation follows regarding a fourth exemplary embodiment. Note that configuration similar to the third exemplary embodiment is allocated the same reference numerals, and explanation is omitted where appropriate.

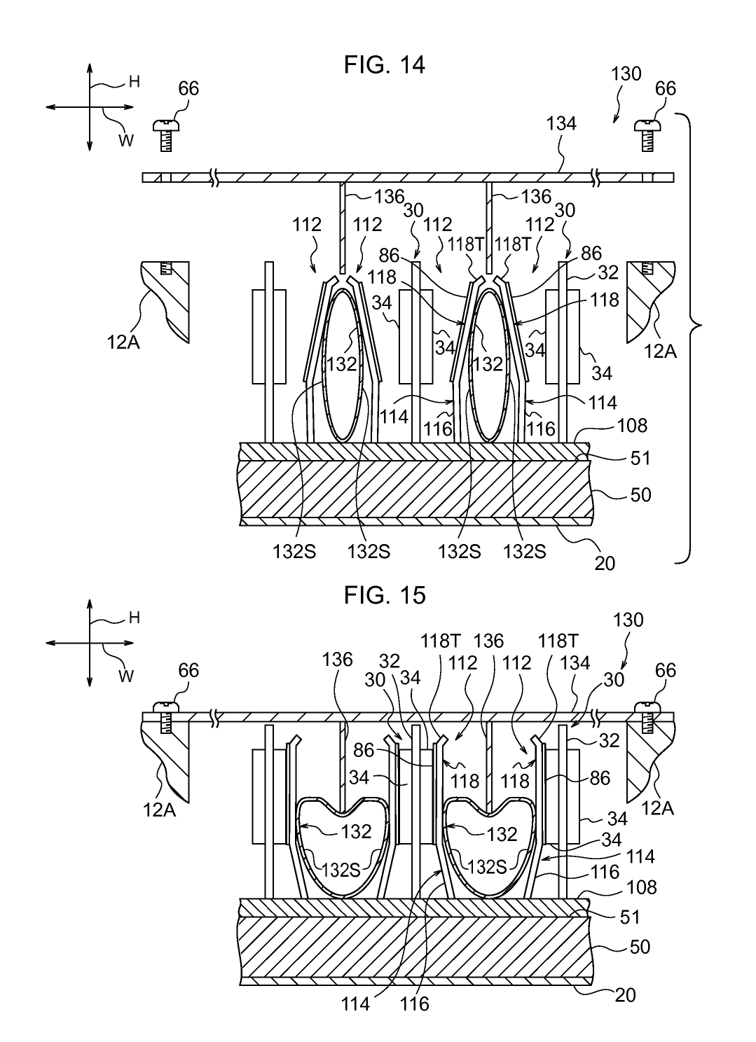

As illustrated in FIG. 14 and FIG. 15, in a cooling structure 130 according to the fourth exemplary embodiment, pairs of heat transfer members 112 are disposed facing in opposite directions to each other between pairs of plate thickness direction adjacent memory cards 30. Resilient members 132, configuring an example of a press contact portion, are disposed together with insertion members 136 between plate-shaped portions 114 of the pairs of heat transfer members 112. The resilient member 132 is formed by a plate spring extending along the height direction of the memory cards 30, and has an elliptical cross-section (see FIG. 14) in an initial state (natural state). The resilient member 132 is disposed between the plate-shaped portions 114 of the pair of heat transfer members 112 with the axial direction in the width direction of the memory cards 30.

A support frame 134 is disposed on the opposite side of the memory cards 30 to the printed circuit board 20. The support frame 134 is formed in a plate shape, with outer peripheral portions of the support frame 134 fixed to fixing portions 12A provided to the casing 12 (see FIG. 1) using screws 66, serving as an example of fixing members. The support frame 134 includes plural of the insertion members 136 that respectively extend between the plate-shaped portions 114 of the pairs of heat transfer members 112 in the fixed state of the support frame 134 to the fixing portion 12A.

As illustrated in FIG. 15, the insertion members 136 are formed in plate shapes, and face the respective plate-shaped portions 114 when in an inserted state between the plate-shaped portions 114 of the pairs of heat transfer members 112. The insertion members 136 squash the resilient members 132 toward the printed circuit board 20 side, such that side portions (portions facing the heat transfer members 72) 132S on both sides of the resilient members 132 bulge out toward the sides of the pair of heat transfer members 112. The side portions 132S deform (resiliently deform) the plate-shaped portions 114 of the pair of heat transfer members 112 in directions heading apart from each other. The respective facing portions 118 of the pair of heat transfer members 112 are accordingly placed in press contact with the memory chips 34 of the opposing memory card 30.

Next, explanation follows regarding an installation and removal method (replacement method) of the memory cards 30 in the fourth exemplary embodiment, together with explanation regarding operation of the fourth exemplary embodiment.

As illustrated in FIG. 14, when mounting the memory cards 30 to the printed circuit board 20, the support frame 134 is removed from the fixing portions 12A, pulling out the insertion members 136 from between the plate-shaped portions 114 of the pairs of heat transfer members 112. The resilient members 132 that were squashed toward the printed circuit board 20 sides by the insertion members 136 return to their original shapes. As a result, the plate-shaped portions 114 of the pairs of heat transfer members 112 return to their original shapes, and the facing portions 118 of the plate-shaped portions 114 move away from the opposing memory chips 34. The memory cards 30 are mounted to the printed circuit board 20 through the memory sockets 40 (see FIG. 3) in this state.

Next, as illustrated in FIG. 15, the plural insertion members 136 provided to the support frame 134 are inserted between the respective pairs of heat transfer members 112, and the support frame 134 is fixed to the fixing portions 12A. The resilient members 132 disposed between the plate-shaped portions 114 of the pairs of heat transfer members 112 are accordingly squashed toward the printed circuit board 20 side by the respective insertion members 136, undergoing resilient deformation. When the resilient members 132 undergo resilient deformation, the respective facing portions 118 of the pairs of heat transfer members 112 are placed in press contact with the memory chips 34 of the opposing memory cards 30 by the side portions 132S on both sides of the resilient members 132. Heat of the memory chips 34 is accordingly transmitted to the pair of flow path members 50 through the heat transfer members 112 and the support members 108, thereby cooling the memory chips 34.

During replacement of the memory cards 30, as described above, the support frame 134 is removed from the fixing portions 12A, pulling out the insertion members 136 from between the pairs of heat transfer members 112. The resilient members 132 and the pairs of heat transfer members 112 return to their original shapes, and the respective facing portions 118 of the pairs of heat transfer members 112 move away from the memory chips 34 of the memory cards 30. The memory cards 30 are replaced in this state.

In the present exemplary embodiment, fixing the support frame 134 to the fixing portions 12A enables the respective facing portions 118 of the pairs of heat transfer members 112 to be placed in press contact with the memory chips 34 of the memory cards 30. The effort demanded by an installation and removal operation of the memory cards 30 is accordingly reduced in comparison to cases in which the facing portions 118 of the pairs of heat transfer members 112 are individually placed in press contact with the memory chips 34 of the opposing memory cards 30.

The facing portions 118 of the heat transfer members 112 are placed in press contact with the memory chips 34 of the memory cards 30 under the biasing force of the resilient members 132, thereby improving close contact properties between the facing portions 118 and the memory chips 34. The cooling efficiency of the memory chips 34 is accordingly improved.

Removing the support frame 134 from the fixing portions 12A enables the respective facing portions 118 of the pairs of heat transfer members 112 to move away from the memory chips 34 of the opposing memory cards 30. The heat transfer members 112 are thereby suppressed from impinging on the memory cards 30 during replacement of the memory cards 30. Damage to the memory cards 30 is accordingly further suppressed.

Explanation follows regarding modified examples of the first to fourth exemplary embodiments. Explanation is given regarding various modified examples applied to the first exemplary embodiment, however the following modified examples may also be applied to the second to fourth exemplary embodiments.

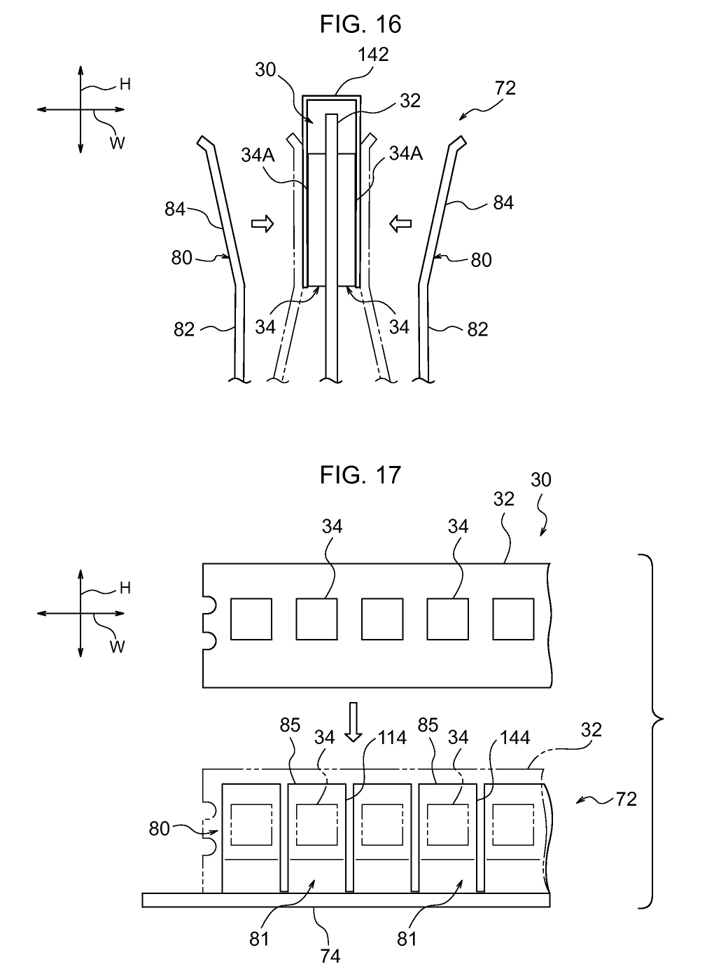

In the first exemplary embodiment, an example is illustrated in which the heat transfer sheet 86 is applied to the facing portion 84 of the heat transfer member 72, however the placement of the heat transfer sheet 86 is not limited thereto. For example, as illustrated in FIG. 16, a heat transfer sheet 142 may be applied to contact faces 34A of the memory chips 34 that contact the heat transfer members 72. The heat transfer sheet 142 is folded over into a U-shape cross-section profile so as to cover the memory chips 34 mounted on both sides of the memory board 32, and is applied to the contact faces 34A of each of the memory chips 34. Note that the heat transfer sheet 86, 142 may be omitted where appropriate.

Moreover, in the first exemplary embodiment, an example is illustrated in which the facing portion 84 of the heat transfer member 72 contacts plural memory chips 34 mounted on one side of the memory card 30, however the configuration of the facing portion 84 is not limited thereto. For example, as illustrated in FIG. 17, slits 144 may be used to divide the plate-shaped portion 80 of the heat transfer member 72 into plural plate-shaped portions 81 corresponding to the number of memory chips 34, and facing portions 85 of each of the plate-shaped portions 81 placed in press contact with the plural memory chips 34. So doing absorbs thickness variation between the plural memory chips 34, for example, thereby improving the cooling efficiency of the respective memory chips 34. Heat transfer sheets may be applied to each of the facing portions 85.

In the first exemplary embodiment, an example is illustrated in which the memory cards 30 serve as a card-type electronic component, however the card-type electronic component may, for example, by configured by a network card or an Input/Output (I/O) card.

In the first exemplary embodiment, an example is illustrated in which the heat sinks 24 are connected in the respective coolant circulation paths J1, J2, however the heat sinks 24 do not have to be connected to the coolant circulation paths J1, J2. Moreover, in the first exemplary embodiment, an example is illustrated in which the pair of flow path members 50A, 50B are formed as separate members, however the flow path members 50A, 50B may be integrally formed and disposed at the periphery of the respective memory card groups M1, M2.

Technology disclosed herein has been explained above with reference to the first to fourth exemplary embodiments, however the technology disclosed herein is not limited to the first to fourth exemplary embodiments, and a combination of the first to fourth exemplary embodiments and the modified examples may be employed. Various configurations of the technology disclosed herein may be implemented within a range not departing from the spirit of the technology disclosed herein.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A cooling structure for a card-type electronic component, comprising:
a printed circuit board on which a card-type electronic component is detachably mounted;
a thermally-conductive heat transfer member, disposed facing the card-type electronic component;
a press contact portion that places the heat transfer member in press contact with the card-type electronic component; and
a pair of flow path portions that are disposed at both width direction sides of the card-type electronic component, that form flow paths in which coolant flows, and that support the heat transfer member so as to enable heat exchange between the heat transfer member and the coolant.

2. The card-type electronic component cooling structure of claim 1, wherein:
the heat transfer member is supported by the pair of flow path portions so as to be capable of rotation in directions toward and away from the card-type electronic component.

3. The card-type electronic component cooling structure of claim 2, wherein:
the heat transfer member includes a shaft portion rotatably supported by the pair of flow path portions, a plate-shaped portion that extends out from the shaft portion to face the card-type electronic component, and an engagement portion formed at the shaft portion; and
the press contact portion is a press contact restriction member that is attached to one of the flow path portions, and that engages with the engagement portion to restrict rotation of the shaft portion in a state in which the plate-shaped portion is in press contact with the card-type electronic component.

4. A cooling structure for a card-type electronic component, comprising:
a printed circuit board on which a plurality of card-type electronic components are detachably mounted at intervals in a plate thickness direction of the card-type electronic components;
a pair of thermally-conductive heat transfer members, disposed between an adjacent pair of the card-type electronic components so as to face the respective card-type electronic components;
a press contact portion that respectively places each of the pair of heat transfer members in press contact with an opposing card-type electronic component; and
a pair of flow path portions that are disposed at both width direction sides of the plurality of card-type electronic components, that form flow paths in which coolant flows, and that support the pair of heat transfer members so as to enable heat exchange with the coolant.

5. The card-type electronic component cooling structure of claim 4, wherein:
the heat transfer members are supported by the pair of flow path portions so as to be capable of rotation in directions toward and away from the respective card-type electronic components.

6. The card-type electronic component cooling structure of claim 5, wherein:
the heat transfer members each include a shaft portion rotatably supported by the pair of flow path portions, a plate-shaped portion that extends out from the shaft portion to face the opposing card-type electronic component, and an engagement portion formed at the shaft portion; and
the press contact portion is a press contact restriction member that is attached to one of the flow path portions, and that engages with the engagement portion to restrict rotation of the shaft portion in a state in which the plate-shaped portion is in press contact with the respective card-type electronic components.

7. The card-type electronic component cooling structure of claim 4, wherein:
the pair of heat transfer members are respectively supported by the pair of flow path portions so as to be capable of rotation in directions toward and away from the respective card-type electronic components; and
the press contact portion is a compression resilient body that is disposed in a compressed state between the pair of heat transfer members, and that respectively biases each of the heat transfer members toward the opposing card-type electronic component.

8. The card-type electronic component cooling structure of claim 7, wherein:
the heat transfer members each include a shaft portion rotatably supported by the pair of flow path portions, a plate-shaped portion that extends out from the shaft portion to face the opposing card-type electronic component, and an engagement portion formed at the shaft portion; and
the card-type electronic component cooling structure further comprises a separation restriction member that is attached to one of the flow path portions, and that engages with the engagement portion to restrict rotation of the shaft portion in a state in which the plate-shaped portion is separated from the opposing card-type electronic component.

9. The card-type electronic component cooling structure of claim 4, wherein:
the pair of heat transfer members are each formed in a plate shape and extend out from the pair of flow path portions to between the adjacent pair of card-type electronic components; and
the press contact portion respectively deforms each of the pair of heat transfer members toward the opposing card-type electronic component, thereby placing the heat transfer members in press contact with the respective card-type electronic components.

10. The card-type electronic component cooling structure of claim 9, wherein:
the press contact portion is a compression resilient body that is disposed in a compressed state between the pair of heat transfer members, and that respectively biases each of the heat transfer members toward the opposing card-type electronic component.

11. The card-type electronic component cooling structure of claim 9, wherein the press contact portion includes:
a hollow resilient member disposed between the pair of heat transfer members; and
an insertion member that is inserted between the pair of heat transfer members to squash the resilient member such that each of the heat transfer members is placed in press contact with the opposing card-type electronic component by the deformed resilient member.

12. The card-type electronic component cooling structure of claim 7, wherein:
stopper portions are provided to free end portions on the opposite side of the pair of heat transfer members to the pair of flow path portions, and the stopper portions respectively project out toward the side of their counterpart and anchor the compression resilient body.

13. The card-type electronic component cooling structure of claim 7, wherein:
the compression resilient body is a plate spring that is formed in a tube shape and is disposed with an axial direction along a width direction of the card-type electronic components.

14. The card-type electronic component cooling structure of claim 1, wherein:
the pair of flow path portions are connected to a cooling heat exchanger that cools the card-type electronic component mounted to the printed circuit board.

15. The card-type electronic component cooling structure of claim 1, wherein:
the card-type electronic component is a memory card.

16. The card-type electronic component cooling structure of claim 15, wherein:
the memory card is mounted with a plurality of memory chips at intervals in a memory card width direction; and
the heat transfer member includes a plurality of facing portions facing each of the plurality of memory chips.

17. The card-type electronic component cooling structure of claim 1, wherein a heat transfer sheet that contacts the card-type electronic component is provided at a contact face of the heat transfer member that contacts the card-type electronic component.

18. An electronic device comprising:
a printed circuit board;
a card-type electronic component detachably mounted to the printed circuit board;
a thermally-conductive heat transfer member, disposed facing the card-type electronic component;
a press contact portion that places the heat transfer member in press contact with the card-type electronic component; and
a pair of flow path portions that are disposed at both width direction sides of the card-type electronic component, that form flow paths in which coolant flows, and that support the heat transfer member so as to enable heat exchange between the heat transfer member and the coolant.
